(19) United States
(12) Patent Application Publication
(10) Pub. No.: US 2026/0313260 A1
(43) Pub. Date: Oct. 8, 2026

(54) IMAGE SENSING DEVICE AND IMAGING SYSTEM

(71) Applicant: SK hynix Inc., Gyeonggi-do (KR)

(72) Inventor: Kazuhiro YAHATA, Tokyo (JP)

(21) Appl. No.: 19/641,554

(22) Filed: Apr. 8, 2026

(30) Foreign Application Priority Data
Apr. 8, 2025 (KR) 10-2025-0045692

(51) Int. Cl. H04N 25/61; H04N 25/11; H04N 25/703; H04N 25/78; H10F 39/00

(52) U.S. Cl. CPC H04N 25/61; H04N 25/703; H04N 25/78; H10F 39/8063; H04N 25/11

(57) ABSTRACT

An image sensing device includes a first flare detection photodiode configured to generate a flare detection signal, a first filter disposed over the first flare detection photodiode, and a first microlens disposed over the first filter to be shifted from a central axis of the first filter by a first offset corresponding to a first angle of incidence of flare light upon the first flare detection photodiode.

### CROSS-REFERENCE TO RELATED APPLICATION(S)

This application claims priority to Korean Patent Application No. 10-2025-0045692, filed on Apr. 8, 2025, the disclosure of which is incorporated herein by reference in its entirety.

### TECHNICAL FIELD

The technology and embodiments disclosed in the present disclosure generally relate to an image sensing device and an imaging system.

### BACKGROUND

An imaging system is a device for capturing optical images by converting light into electrical signals using a photosensitive semiconductor material which reacts to light. With the development of automotive, medical, computer and communication industries, the demand for high-performance imaging systems has been increasing in various fields such as smartphones, digital cameras, game machines, IoT (Internet of Things), robots, security cameras, and medical micro cameras.

When an image is captured by the imaging system, lens flare may occur due to strong light. Such lens flare, can lead to issues such as reduction in image contrast, and thus, it is necessary to detect the occurrence of lens flare.

### SUMMARY

Various embodiments of the present disclosure relate to an imaging device including at least one flare detection pixel, which can determine occurrence or non-occurrence of flare using the flare detection pixel.

Various embodiments of the present disclosure relate to an image sensing device in which at least one microlens is arranged to increase the sensitivity of photodiodes in a direction in which flare light is incident.

In accordance with an embodiment of the present disclosure, an image sensing device may include a first flare detection photodiode configured to generate a flare detection signal, a first filter disposed over the first flare detection photodiode, and a first microlens disposed over the first filter to be shifted from a central axis of the first filter by a first offset corresponding to a first angle of incidence of flare light upon the first flare detection photodiode.

In some embodiments, the first angle of incidence of the flare light may correspond to an angle of incidence of light incident upon the first flare detection photodiode from outside an exit pupil.

In some embodiments, the image sensing device may further include an image photodiode configured to generate an image signal, a second filter disposed over the image photodiode, and a second microlens disposed over the second filter to be shifted from a central axis of the second filter by a second offset. A magnitude of the first offset is smaller than a magnitude of the second offset.

In some embodiments, the second offset may correspond to a second angle of incidence of light incident upon the image photodiode from an exit pupil.

In some embodiments, the first offset may have a sign identical to the second offset.

In some embodiments, the first offset may have a sign different from the second offset.

In some embodiments, the second filter may be a color filter including at least one color selected from red, green, or blue.

In some embodiments, the first filter may be a transparent filter.

In some embodiments, the first flare detection photodiode may be disposed inside an image circle.

In some embodiments, the first flare detection photodiode may be disposed inside an optical black region.

In some embodiments, the first flare detection photodiode may be disposed outside an optical black region.

In some embodiments, the first flare detection photodiode may be disposed outside an image circle.

In some embodiments, the image sensing device may further include a second flare detection photodiode disposed adjacent to the first flare detection photodiode, wherein the first filter is disposed over both the first flare detection photodiode and the second flare detection photodiode.

In accordance with an embodiment of the present disclosure, an imaging system may include an image sensing device and an image processing device. The image sensing device may include a first flare detection pixel configured to detect flare light incident from outside an exit pupil to generate a first flare detection signal, and a readout circuit configured to generate a first flare detection pixel value based on the first flare detection signal. The image processing device may determine whether flare has occurred based on the first flare detection pixel value.

In some embodiments, the first flare detection pixel may be disposed outside an image circle.

In some embodiments, the image processing device may determine that the flare has occurred when the first flare detection pixel value is equal to or greater than a first threshold.

In some embodiments, the image sensing device may include a second flare detection pixel that shares a microlens with the first flare detection pixel and is configured to detect the flare light incident from outside the exit pupil to generate a second flare detection signal. The readout circuit may generate a second flare detection pixel value based on the second flare detection signal. The image processing device may determine whether the flare has occurred based on the first flare detection pixel value and the second flare detection pixel value.

In some embodiments, the first flare detection pixel and the second flare detection pixel may be disposed inside the image circle and outside the optical black region.

In some embodiments, the image processing device may determine that the flare has occurred, when a ratio of a first value to a second value is less than a second threshold or is greater than a third threshold. The first value is obtained by subtracting a black level from the first flare detection pixel value, and the second value is obtained by subtracting the black level from the second flare detection pixel value.

In accordance with an embodiment of the present disclosure, an imaging system may include an image sensing device and an image processing device. The image sensing device may include a first flare detection photodiode configured to generate a first flare detection signal, a second flare detection photodiode configured to generate a second flare detection signal, a transparent filter disposed over both the first flare detection photodiode and the second flare detection photodiode, a microlens disposed over the transparent filter with an offset corresponding to an angle of incidence of light incident upon the first flare detection photodiode or the second flare detection photodiode from outside an exit pupil, and a readout circuit configured to generate a first flare detection pixel value based on the first flare detection signal and to generate a second flare detection pixel value based on the second flare detection signal. The image processing device may determine whether flare has occurred based on the first flare detection pixel value, the second flare detection pixel value, and a black level.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an imaging system according to an embodiment of the present disclosure.

FIG. 2 is a diagram illustrating an image sensing device according to an embodiment of the present disclosure.

FIG. 3 is a diagram illustrating a pixel region according to an embodiment of the present disclosure.

FIG. 4 is a diagram illustrating a pixel according to an embodiment of the present disclosure.

FIG. 5 is a diagram illustrating a pixel according to an embodiment of the present disclosure.

FIG. 6 is a diagram illustrating an image sensing device according to an embodiment of the present disclosure.

FIG. 7 is a diagram illustrating a pixel region according to an embodiment of the present disclosure.

FIG. 8 is a diagram illustrating a pixel region according to an embodiment of the present disclosure.

FIG. 9 is a diagram illustrating a pixel according to an embodiment of the present disclosure.

FIG. 10 is a diagram illustrating a pixel according to an embodiment of the present disclosure.

FIG. 11 is a diagram illustrating an image sensing device according to an embodiment of the present disclosure.

FIG. 12 is a diagram illustrating an offset according to an embodiment of the present disclosure.

FIG. 13 is a diagram illustrating an image sensing device according to an embodiment of the present disclosure.

FIG. 14 is a diagram illustrating an offset according to an embodiment of the present disclosure.

FIG. 15 is a diagram illustrating an imaging system according to an embodiment of the present disclosure.

FIG. 16 is a diagram illustrating an imaging system according to an embodiment of the present disclosure.

FIG. 17 is a diagram illustrating an imaging system according to an embodiment of the present disclosure.

FIG. 18 is a block diagram showing an example of a computing device corresponding to the image processing device of FIG. 1 according to an embodiment of the present disclosure.

### DETAILED DESCRIPTION

The present disclosure provides embodiments and examples of an image sensing device and an imaging system that may be used in configurations to substantially address one or more technical or engineering issues and to mitigate limitations or disadvantages encountered in some image sensing devices. Some embodiments of the present disclosure relate to an imaging device including at least one flare detection pixel, which can determine occurrence or non-occurrence of flare using the flare detection pixel. Some embodiments of the present disclosure relate to an image sensing device in which at least one microlens is arranged to increase the sensitivity of photodiodes in a direction in which flare light is incident. In recognition of the issues above, the present disclosure may provide the imaging system that can determine whether flare has occurred by using pixel values of flare detection pixels. Since the image sensing device includes high-sensitivity pixels arranged in the direction in which flare light is incident, the image sensing device may accurately determine occurrence or non-occurrence of flare by using the high-sensitivity pixels.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Various embodiments will be described with reference to the accompanying drawings. However, it should be understood that the present disclosure is not limited to the specific embodiments, but includes various modifications, equivalents, and/or alternatives of the embodiments. The embodiments of the present disclosure may provide a variety of effects that can be directly or indirectly recognized through the present disclosure.

Embodiments of the present disclosure will be described in detail with reference to the accompanying drawings so that the present disclosure may be easily realized by those skilled in the art. However, it should be noted that the present disclosure may be achieved in various different forms and is not limited to the embodiments described herein.

In the following description of embodiments of the present disclosure, detailed descriptions of well-known functions and configurations incorporated herein will be omitted when they may make the subject matter of the present disclosure unclear. In the drawings, parts that are not related to the description of the present disclosure are omitted for clarity, and like reference numbers will be used throughout the specification to refer to like parts.

In the present disclosure, when a component is referred to as being “connected”, “coupled”, or “joined” to another component, it may refer to either a direct connection relationship but also an indirect connection relationship in which another component is present therebetween. In addition, when a component “comprises”, “includes” or “has” another component, the component does not exclude additional components unless specifically stated, but may further include other components.

In the present disclosure, terms such as “first”, “second”, etc., are used only to distinguish one element from other elements and but are not used to limit elements, and they do not imply order or importance, etc., of elements unless otherwise specified. Accordingly, within the scope of the present disclosure, a first element in one embodiment may be referred to as a second element in another embodiment, and vice versa.

In the following description, components are distinguished from each other to clearly describe their characteristics, but this does not necessarily mean that they are physically separate. That is, a plurality of components may be integrated into one hardware or software module and one component may be divided into a plurality of hardware or software modules. Accordingly, integrated or divided embodiments are within the scope of the present disclosure even if not specifically stated.

In the following description, components described with reference to various embodiments are not all necessarily required, and some components may be selectively used. Accordingly, embodiments including only some of the components described in one embodiment are also within the scope of the present disclosure. Further, embodiments including components not explicitly described are also within the scope of the present disclosure.

In the present disclosure expressions of positional relationships such as “top”, “upper”, “bottom”, “lower”, “left”, “right”, etc., are used for convenience of explanation, and when the drawings illustrated in the present specification are viewed in reverse, the positional relationships described in the specification may be interpreted in the opposite way.

In the present disclosure, each of phrases such as “A or B”, “at least one of A and B”, “at least one of A or B”, “A, B, or C”, “at least one of A, B, and C”, “and “at least one of A, B, or C” may refer to any one or all possible combinations of the listed items. The term “and/or” may indicate a combination of a plurality of items or any one of a plurality of listed items. For example, “A or B” may include “only A”, “only B”, or “both A and B”.

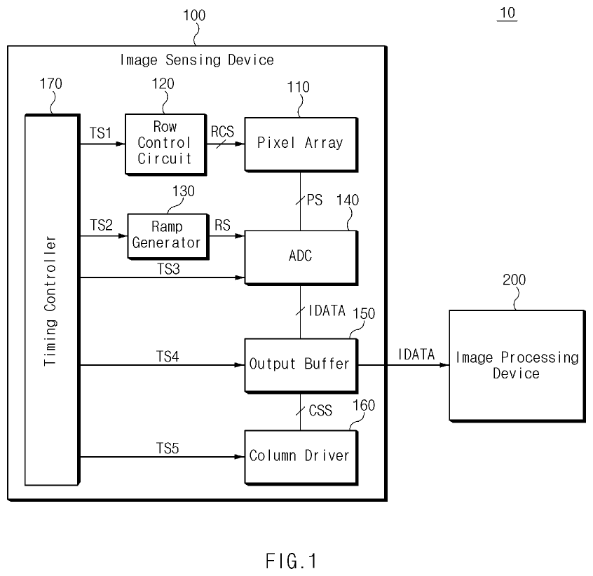

Exemplary embodiments of the present disclosure will be described in detail with reference to FIGS. 1 to 18.

FIG. 1 is a block diagram illustrating an example of an imaging system 10 according to an embodiment of the present disclosure.

Referring to FIG. 1, the imaging system 10 may refer to a device, for example, a digital still camera for photographing still images or a digital video camera for photographing moving images. For example, the imaging system 10 may be implemented as a Digital Single Lens Reflex (DSLR) camera, a mirrorless camera, or a smartphone, but is not limited thereto. The imaging system 10 may include a device having an image pickup element such that the device can capture (or photograph) a target object and can thus create an image of the target object.

The imaging system 10 may include an image sensing device 100 and an image processing device 200. The image processing device 200 may correspond to an image signal processor (ISP).

The image sensing device 100 may be a complementary metal oxide semiconductor (CMOS) image sensor (CIS) configured to convert an incident light into an electrical signal. The image sensing device 100 may include a pixel array 110, a row control circuit 120, a ramp generator 130, an analog-to-digital converter (ADC) 140, an output buffer 150, a column driver 160, and a timing controller 170. The components of the image sensing device 100 illustrated in FIG. 1 are merely provided by way of examples, and it should be understood by one skilled in the art that various changes, substitutions, modifications, and equivalents may be made without departing from the scope of the present disclosure.

The pixel array 110 may include a plurality of pixels arranged in rows and columns. In some embodiments, the plurality of pixels may be arranged in a two-dimensional (2D) pixel array including rows and columns. In some embodiments, the plurality of image pixels may be arranged in a three-dimensional (3D) pixel array. The plurality of pixels may convert an optical signal into an electrical signal on a pixel basis or a pixel group basis, and the pixels in a pixel group share at least certain internal circuitry. The pixel array 110 may receive row control signals (RCS), including a row selection signal, a pixel reset signal and a transfer signal, from the row control circuit 120. Upon receiving the RCSs, corresponding pixels in the pixel array 110 may be activated to perform the operations corresponding to the row selection signal, the pixel reset signal, and the transfer signal.

Each pixel in the pixel array 110 may have at least two different sensitivities. The sensitivity may represent a change in image data (IDATA), in response to an increase in the intensity of incident light. That is, as the sensitivity increases, the amount of image data (IDATA) in response to an increase in the intensity of incident light increases. As the sensitivity decreases, the amount of image data (IDATA) in response to an increase in the intensity of incident light decreases. In the present disclosure, the sensitivity may be determined by a conversion gain.

The row control circuit 120 may activate the pixel array 110 to perform specific operations on the pixels included in the corresponding row based on commands and control signals (TS1) provided by the timing controller 170. The row control circuit 120 may include a row driver. In some embodiments, the row control circuit 120 may select at least one pixel arranged in at least one row of the pixel array 110. The row control circuit 120 may generate a row selection signal to select at least one row among the plurality of rows. The row control circuit 120 may sequentially enable the pixel reset signal and the transfer signal for the pixels corresponding to the at least one selected row. Thus, a reference signal and an image signal, which are analog signals generated by each of the pixels of the selected row, may be sequentially transferred to the ADC 140. The reference signal may be an electrical signal that is provided to the ADC 140 when a sensing node of a pixel, e.g., a floating diffusion region, is reset, and the image signal may be an electrical signal that is provided to the ADC 140 when photocharges generated by the pixel are accumulated in the sensing node. The reference signal indicating unique reset noise of each pixel and the image signal indicating the intensity of incident light may be generically referred to as a pixel signal.

The CMOS image sensor may use the correlated double sampling (CDS) to remove undesired offset values of pixels known as the fixed pattern noise by sampling a pixel signal twice to remove the difference between two samples. In one example, the CDS may remove the undesired offset value of pixels by comparing pixel output voltages obtained before and after photocharges generated by incident light are accumulated in the sensing node, such that only pixel output voltages based on the incident light can be measured. In some embodiments, the ADC 140 may sequentially sample and hold the reference signal and the image signal, which are provided from each of a plurality of column lines from the pixel array 110.

The ramp generator 130 may generate a ramp signal (RS) required for the analog-to-digital conversion (ADC) operation of the ADC 140 upon receiving a timing signal (TS2) from the timing controller 170, and may supply the ramp signal to the ADC 140.

The ADC 140 may sample and hold the pixel signal from each column line of the pixel array 110 based on a timing signal (TS3) of the timing controller 170, may convert the resultant signal into digital signals, and may output the digital signals. In some embodiments, the ADC 140 may be implemented as a ramp-compare type ADC. The ramp-compare type ADC may include a comparator circuit for comparing the analog pixel signal with a ramp signal that ramps up or down over time, and a counter for performing counting until the ramp signal matches the analog pixel signal.

The output buffer 150 may temporarily hold the column-based image data, i.e., image data (IDATA) obtained through digital conversion of the pixel signal, provided from the ADC 140 to output the image data (IDATA). The image data (IDATA) output from the ADC 140 may be temporarily stored in the output buffer 150 based on a timing signal (TS4) of the timing controller 170. The output buffer 150 may provide an interface to compensate for differences in data rate or transfer rate between the image sensing device 100 and other devices.

The column driver 160 may select a column of the output buffer 150 based on a control signal (TS5) from the timing controller 170, and may control the output buffer 150 to sequentially output the image data (IDATA), which are temporarily stored in the selected column of the output buffer 150. In some embodiments, upon receiving an address signal from the timing controller 170, the column driver 160 may generate a column selection signal (CSS) based on the address signal and may select a column of the output buffer 150, thereby outputting the image data (IDATA) as an output signal from the selected column of the output buffer 150.

The timing controller 170 may control operations of at least one of the row driver 120, the ramp generator 130, the ADC 140, the output buffer 150, or the column driver 160.

The timing controller 170 may provide at least one of the row driver 120, the ramp generator 130, the ADC 140, the output buffer 150, or the column driver 160 with a clock signal required for the operations of the respective components of the image sensing device 100, a control signal for timing control, and address signals for selecting a row or column. In some embodiments, the timing controller 170 may include a logic control circuit, a phase-locked loop (PLL) circuit, a timing control circuit, and a communication interface circuit.

The image processing device 200 may perform image signal processing on the image data (IDATA) received from the image sensing device 100. The image processing device 200 may reduce noise in the image data (IDATA), and may perform various kinds of image signal processing, such as interpolation, synthesis, gamma correction, color filter array interpolation, color matrix, color correction, color enhancement, and lens distortion correction, for image-quality improvement of the image data (IDATA). In addition, the image processing device 200 may compress image data that has been created by execution of image signal processing for image-quality improvement, such that the image processing device 200 can create an image file using the compressed image data. Alternatively, the image processing device 200 may recover image data from the image file. In this case, the format for compressing such image data may be a reversible format or an irreversible format. As an example of the compression format, for a still image, Joint Photographic Experts Group (JPEG) format, JPEG 2000 format, or the like may be used. In addition, for moving images, a plurality of frames may be compressed according to Moving Picture Experts Group (MPEG) standards to create moving image files. For example, image files may be created according to Exchangeable image file format (Exif) standards.

The image processing device 200 may generate an HDR image by synthesizing at least two images having different sensitivities. For example, the image sensing device 100 may output a low-sensitivity image generated from a low-sensitivity pixel, e.g., a low conversion gain (LCG) pixel, with a relatively lower sensitivity and a high-sensitivity image generated from a high-sensitivity pixel, e.g., a high conversion gain (HCG) pixel, with a relatively higher sensitivity. The image processing device 200 may combine the low-sensitivity image and the high-sensitivity image to generate an HDR image. Here, the low-sensitivity and the high-sensitivity may correspond to relative concepts, and the image sensing device 100 may generate image data (IDATA) having at least N different sensitivities, where N is an integer greater than or equal to 2. The image processing device 200 may generate HDR images from the image data (IDATA).

The image processing device 200 may transmit the processed image data to a host device (not shown). The host device (not shown) may be a processor, e.g., an application processor, for processing the image-processed image data received from the image processing device 200; a memory, e.g., a non-volatile memory for storing the image data; or a display device, e.g., a liquid crystal display (LCD), for visually displaying the image data.

In addition, the image processing device 200 may transmit a control signal, e.g., whether or not to operate, an operation timing, an operation mode, etc., for controlling operations of the image sensing device 100 to the image sensing device 100.

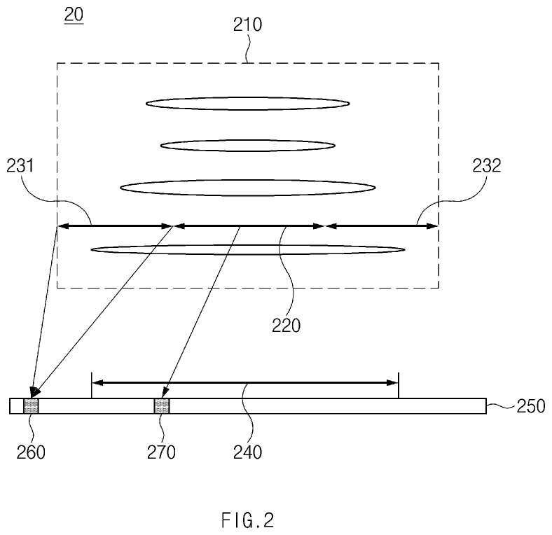

FIG. 2 is a diagram illustrating an image sensing device 20 according to an embodiment of the present disclosure. The image sensing device 20 corresponds to the image sensing device 100 of FIG. 1.

Referring to FIG. 2, the image sensing device 20 according to an embodiment of the present disclosure may include a main lens 210 and a pixel region 250.

The main lens 210 may include multiple lenses that collect light and direct the collected light to be incident upon the pixels.

Depending on the configuration of the main lens 210, the range of the exit pupil 220, outer sides (231, 232) of the exit pupil 220, and the range of the image circle 240 may be determined. In the imaging system, the path of light may be adjusted while passing through multiple lenses, and the position of an imaginary exit through which the light finally emerges after passing through the lenses may be referred to as an exit pupil 220. Accordingly, light is generally incident from the exit pupil 220 onto the pixel region 250; however, due to the occurrence of lens flare, there may also be light incident from the outer sides (231, 232) of the exit pupil 220 onto the pixel region 250.

The pixel region 250 may refer to a region in which pixels may be arranged. For example, the pixel region 250 may include at least one flare detection pixel 260 and at least one image pixel 270.

The flare detection pixel 260 may refer to a pixel that detects flare light. By detecting flare light, the flare detection pixel 260 may generate a flare detection signal. More specific details regarding the configuration of the flare detection pixel 260 will be described later.

The flare detection pixel 260 may be disposed outside the image circle 240. The outside of the image circle 240 may represent a region in which little light is incident from the exit pupil 220. Light may be incident from the outer sides (231, 232) of the exit pupil 220 toward the outside of the image circle 240. Accordingly, when an amount of light equal to or greater than a first threshold is detected outside the image circle 240, such light may be identified as flare flight. Therefore, since the flare detection pixel 260 is disposed outside the image circle 240, the flare detection pixel 260 can detect flare light.

The image pixel 270 may refer to a pixel that generates an image signal. The image signal may be used to generate an image. The image pixel 270 may be disposed inside the image circle 240.

Although not shown in FIG. 2, the image sensing device 20 may include a readout circuit. The readout circuit may generate pixel values based on signals received from the flare detection pixels 260 and the image pixels 270. For example, the readout circuit may generate a flare detection pixel value based on the flare detection signal and an image pixel value based on the image signal.

The image processing device may determine that flare has occurred when the flare detection pixel value is equal to or greater than a first threshold. Here, the first threshold may be a value greater than a noise level. In addition, the image processing device may determine that flare has occurred when the ratio of the number of pixel values equal to or greater than the first threshold to the total number of multiple flare detection pixel values generated by multiple flare detection pixels, is equal to or greater than a predetermined ratio. For example, when the ratio of the number of pixel values that are equal to or greater than the first threshold to the total number of the flare detection pixel values is 10% or greater, the image processing device may determine that flare has occurred.

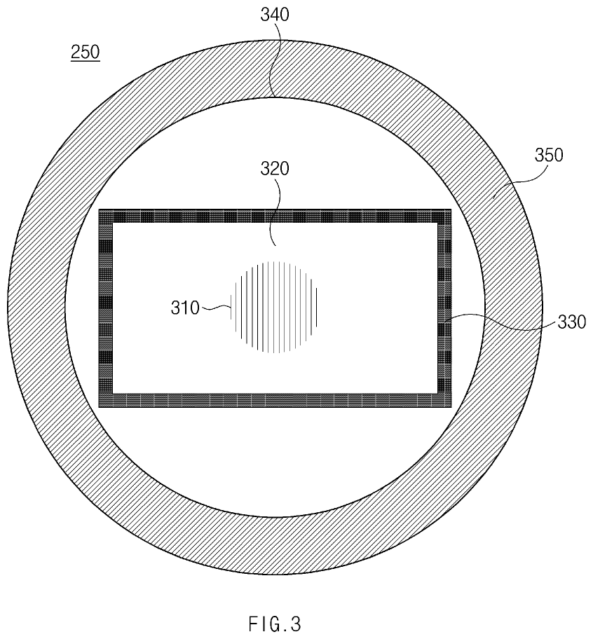

FIG. 3 is a diagram illustrating the pixel region 250 according to an embodiment of the present disclosure.

The embodiments of FIG. 3 will be described with reference to FIG. 2.

Referring to FIG. 3, the pixel region 250 according to an embodiment of the present disclosure may include an image pixel region 320, an optical black region 330, and a flare detection pixel region 350. FIG. 3 is a top view of the pixel region 250 shown in FIG. 2. In FIG. 3, an exit pupil 310 corresponding to the exit pupil 220 of FIG. 2 and an image circle 340 corresponding to the image circle 240 of FIG. 2 are illustrated.

The image pixel region 320 may be a region in which image pixels are arranged.

The optical black region 330 may represent a region including pixels that are kept in a light-blocked state. Since light is blocked, the optical black region 330 may be used to measure a black level of the image sensing device, or may be used to remove noise from the image sensing device.

The flare detection pixel region 350 may be a region in which flare detection pixels are arranged. The flare detection pixel region 350 may be disposed outside the image circle 340.

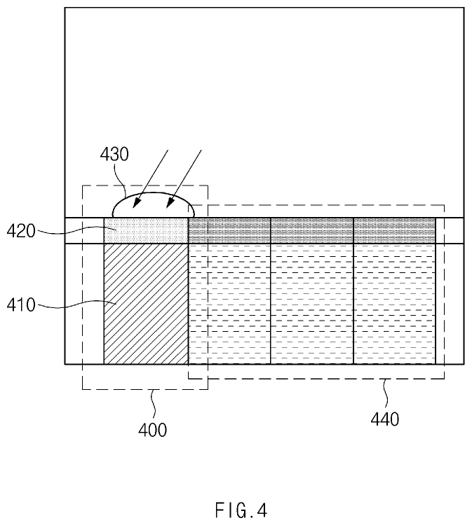

FIG. 4 is a diagram illustrating a pixel according to an embodiment of the present disclosure.

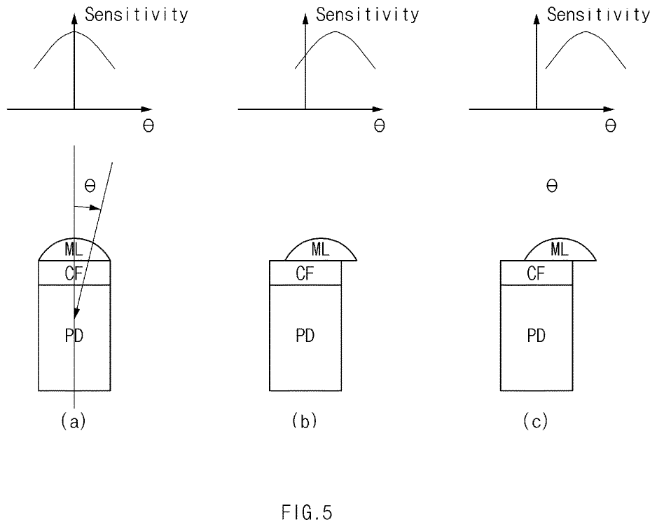

FIG. 5 is a diagram illustrating a pixel according to an embodiment of the present disclosure.

The structure of FIG. 4 will be described with reference to FIG. 5.

Referring to FIG. 4, the flare detection pixel 400 may include a flare detection photodiode 410, a filter 420, and a microlens 430.

The flare detection photodiode 410 may be a photodiode that generates a flare detection signal by detecting flare light. The flare detection photodiode 410 may be disposed outside the image circle. In FIG. 4, the flare detection photodiode 410 is illustrated as being disposed outside the optical black region 440, but the arrangement of the flare detection photodiode 410 according to various embodiments of the present disclosure is not limited thereto.

The filter 420 may be disposed at an upper end of the flare detection photodiode 410. The filter 420 may be a transparent filter. The microlens 430 may be disposed at an upper end of the filter 420. Specifically, the microlens 430 may be disposed at an upper end of the filter 420 with a predetermined offset. The offset may indicate the degree to which the microlens 430 is relatively shifted from the center of the pixel. Specifically, referring to FIG. 5, the angles of incidence of light incident upon the photodiodes (PDs) included in the image sensing device are different from each other, and the sensitivity to the incident light changes depending on the position where the microlens (MLS) is disposed at the upper end of the color filter (CF), and thus the offsets of the microlenses (MLS) included in the pixels may vary. For example, the offset of (b) of FIG. 5 may be larger than the offset of (a) of FIG. 5, and the offset of (c) of FIG. 5 may be greater than the offset of (b) of FIG. 5. Therefore, the microlenses 430 may be arranged to increase the sensitivity of the flare detection photodiode 410 in a direction in which the flare light is incident. For example, the microlens 430 may be disposed at the upper end of the filter 420 with an offset corresponding to the angle of incidence of flare light upon the flare detection photodiode 410. In addition, the angle of incidence of flare light upon the flare detection photodiode 410 may correspond to the angle of incidence of light transferred from outside an exit pupil to the flare detection photodiode 410.

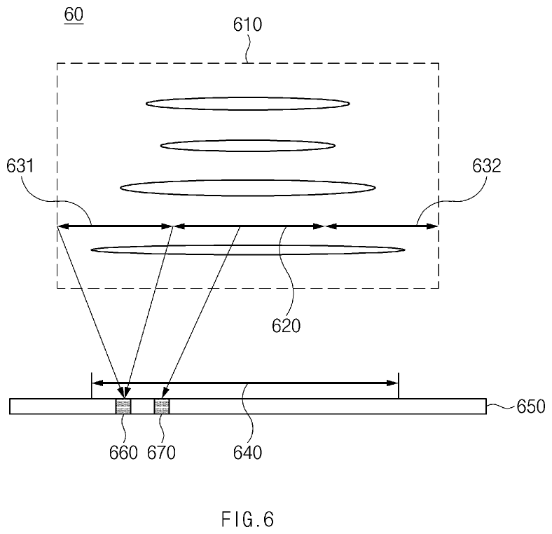

FIG. 6 is a diagram illustrating an image sensing device 60 according to an embodiment of the present disclosure.

Referring to FIG. 6, the image sensing device 60 according to an embodiment of the present disclosure may include a main lens 610 and a pixel region 650.

The main lens 610 may include lenses that collect light and direct the collected light to be incident upon the pixels.

Depending on the configuration of the main lens 610, the range of the exit pupil 620, the outer sides (631, 632) of the exit pupil 620, and the range of the image circle 640 may be determined. In general, light is incident from the exit pupil 620 onto the pixel region 650; however, when lens flare occurs, light may also be incident from the outer sides (631, 632) of the exit pupil 620 onto the pixel region 650.

The pixel region 650 may include at least one flare detection pixel 660 and at least one image pixel 670.

The flare detection pixel 660 may generate a flare detection signal by detecting flare light. The flare detection pixel 660 may be disposed inside the image circle 640. Light may be incident from the outer sides (631, 632) of the exit pupil 620 toward the inside of the image circle 640. Therefore, since the flare detection pixel 660 is disposed inside the image circle 640, the flare detection pixel 660 may detect flare light.

The image pixel 670 may generate an image signal. The image signal may be used to generate an image. The image pixel 670 may be disposed inside the image circle 640.

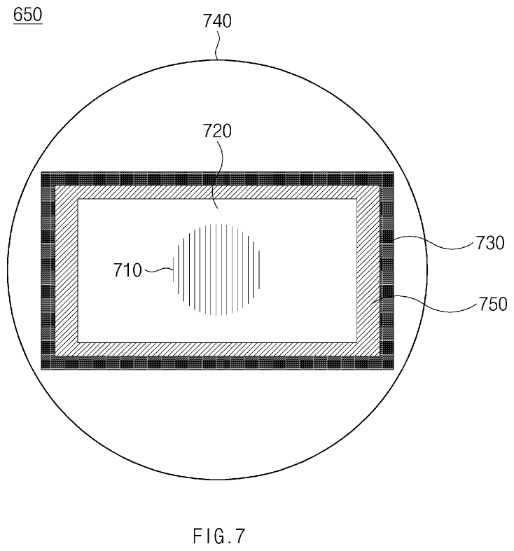

FIG. 7 is a diagram illustrating a pixel region according to an embodiment of the present disclosure.

The structure of FIG. 7 will be described with reference to FIG. 6.

Referring to FIG. 7, the pixel region 650 according to an embodiment of the present disclosure may include an image pixel region 720, an optical black region 730, and a flare detection pixel region 750. FIG. 7 is a top view of the pixel region 650 of FIG. 6. In FIG. 7, an exit pupil 710 corresponding to the exit pupil 620 of FIG. 6 and an image circle 740 corresponding to the image circle 640 of FIG. 6 are illustrated.

The image pixel region 720 may be a region in which image pixels are arranged.

The optical black region 730 may include pixels kept in a light-blocked state.

The flare detection pixel region 750 may be a region in which flare detection pixels are arranged. The flare detection pixel region 750 may be disposed inside the image circle 740. In addition, the flare detection pixel region 750 may be disposed inside the optical black region 730. Furthermore, the flare detection pixel region 750 may be located outside the image pixel region 720.

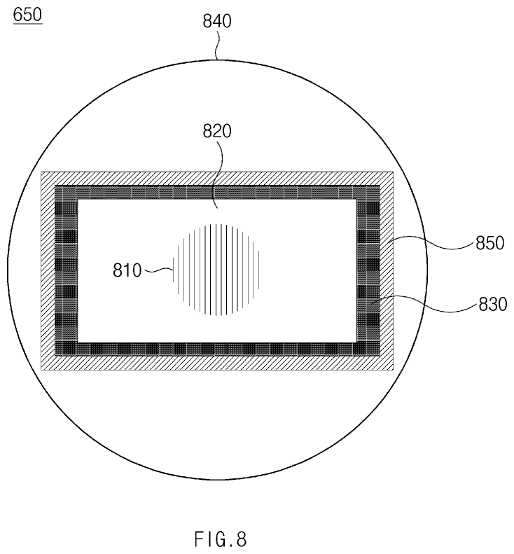

FIG. 8 is a diagram illustrating a pixel region according to an embodiment of the present disclosure.

Hereinafter, the structure of FIG. 8 will be described with reference to FIG. 6.

Referring to FIG. 8, the pixel region 650 according to an embodiment of the present disclosure may include an image pixel region 820, an optical black region 830, and a flare detection pixel region 850. FIG. 8 is a top view of the pixel region 650 of FIG. 6. In FIG. 8, an exit pupil 810 corresponding to the exit pupil 620 of FIG. 6 and an image circle 840 corresponding to the image circle 640 of FIG. 6 are illustrated.

The image pixel region 820 may be a region in which image pixels are arranged.

The optical black region 830 may include pixels kept in a light-blocked state.

The flare detection pixel region 850 may be a region in which flare detection pixels are arranged. The flare detection pixel region 850 may be located inside the image circle 840. In addition, the flare detection pixel region 850 may be located outside the optical black region 830.

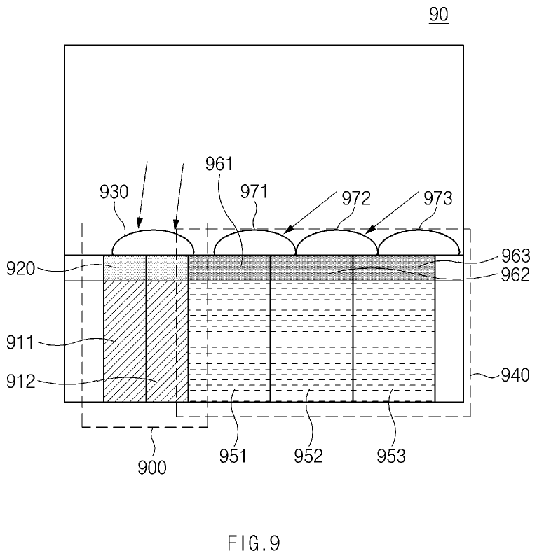

FIG. 9 is a diagram illustrating a pixel according to an embodiment of the present disclosure.

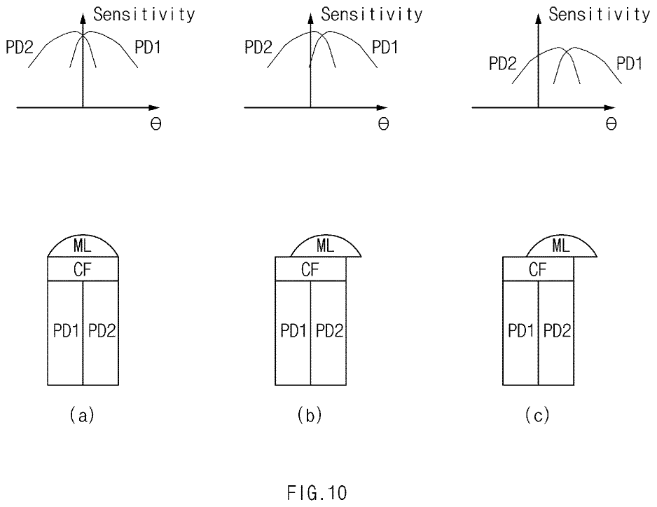

FIG. 10 is a diagram illustrating a pixel according to an embodiment of the present disclosure.

FIG. 9 will be described in detail with reference to FIG. 10.

Referring to FIG. 9, the image sensing device 90 may include flare detection pixels 900 and image pixels 940.

The flare detection pixel 900 may include a first flare detection photodiode 911, a second flare detection photodiode 912, a filter 920, and a microlens 930.

The first flare detection photodiode 911 may generate a first flare detection signal. The second flare detection photodiode 912 may generate a second flare detection signal. The first flare detection photodiode 911 and the second flare detection photodiode 912 may be disposed inside the image circle. In addition, the first flare detection photodiode 911 and the second flare detection photodiode 912 may be disposed outside the optical black region. Alternatively, the first flare detection photodiode 911 and the second flare detection photodiode 912 may be disposed inside the optical black region. Furthermore, the first flare detection photodiode 911 and the second flare detection photodiode 912 may be disposed outside the image pixel region.

The filter 920 may be disposed at upper ends of the first flare detection photodiode 911 and the second flare detection photodiode 912. The filter 920 may be a transparent filter.

The microlens 930 may be disposed at an upper end of the filter 920. The first flare detection photodiode 911 and the second flare detection photodiode 912 may share the microlens 930. Specifically, the microlens 930 may be disposed at an upper end of the filter 920 with a first offset. For example, the microlens 930 may be disposed at a position shifted from the central axis of the filter 920 by the first offset. Specifically, referring to FIG. 10, the angles of incidence of light incident upon the photodiodes (PD1, PD2) included in the image sensing device 90 may differ from each other. The sensitivity to incident light may vary depending on the positions where the microlenses (ML) are disposed over the color filters (CF), and thus the offsets of the microlenses (MLS) included in the pixels may vary. For example, the offset magnitude in (a) of FIG. 10 may be less than that in (b) of FIG. 10, and the offset magnitude in (b) of FIG. 10 may be less than that in (c) of FIG. 10. Therefore, the microlens 930 may be arranged such that the sensitivity of the first flare detection photodiode 911 and the sensitivity of the second flare detection photodiode 912 increase in the direction in which flare light is incident. For example, the microlens 930 may be disposed over the filter 920 with an offset corresponding to the angle of incidence of flare light upon the first flare detection photodiode 911 or the second flare detection photodiode 912. In addition, the angle of incidence of flare light upon the first flare detection photodiode 911 or the second flare detection photodiode 912 may correspond to the angle of incidence of light entering the first flare detection photodiode 911 and the second flare detection photodiode 912 from outside the exit pupil.

The image pixels 940 may include image photodiodes (951, 952, 953), filters (961, 962, 963), and microlenses (971, 972, 973).

The image photodiodes (951, 952, 953) may generate image signals.

The filters (961, 962, 963) may be disposed over the image photodiodes (951, 952, 953), respectively. Each of the filters (961, 962, 963) may include a color. Specifically, the filters (961, 962, 963) may be color filters including at least one color selected from red, green, or blue. For example, the filters (961, 963) may be green filters, and the filter 962 may be a red filter, but the present disclosure is not limited thereto.

The microlenses (971, 972, 973) may be respectively disposed over the filters (961, 962, 963) with a predetermined offset therebetween. For example, the microlens 971 may be disposed over the filter 961 with a second offset. The second offset may correspond to the angle of incidence of light transferred from the exit pupil to the image photodiode 951. As shown in FIG. 9, the magnitude of the first offset may be smaller than the magnitude of the second offset.

Although not shown in FIG. 9, the image sensing device 90 may include a readout circuit. The readout circuit may generate a first flare detection pixel value based on the first flare detection signal and a second flare detection pixel value based on the second flare detection signal. In addition, the readout circuit may generate image pixel values based on the image signals.

The image processing device may determine whether flare has occurred based on the first flare detection pixel value and the second flare detection pixel value. For example, the image processing device may determine that flare has occurred when the ratio of a first value, which is obtained by subtracting a black level from the first flare detection pixel value, to a second value, which is obtained by subtracting the black level from the second flare detection pixel value, is less than a second threshold or greater than a third threshold. The above-described results can be expressed mathematically as represented by Equation 1 and Equation 2.

$$\frac{( {I}_{1} - {I}_{d} )}{( {I}_{2} - {I}_{d} )} < {R}_{l ower} \qquad [ Equation 1 ]$$

$$\frac{( {I}_{1} - {I}_{d} )}{( {I}_{2} - {I}_{d} )} > {R}_{u pper} \qquad [ Equation 2 ]$$

In Equations 1 and 2, I₁ represents the first flare detection pixel value, I₂ represents the second flare detection pixel value, I_{d} represents the black level, R_{lower} represents the second threshold, and Rᵤₚₚₑᵣ represents the third threshold.

The second threshold and the third threshold may be determined based on the first flare detection pixel value and the second flare detection pixel value when flare has not occurred. For example, the second threshold may be the smallest ratio of a first value (I₁−I_{d}) to a second value (I₂−I_{d}) when flare has not occurred, and the third threshold may be the largest ratio of a first value (I₁−I_{d}) to a second value (I₂−I_{d}) when flare has not occurred.

In addition, the second threshold and the third threshold may also be calculated as represented by Equation 3.

$$R ( n ) = \frac{{I}_{1} ( n ) - {I}_{d}}{{I}_{2} ( n ) - {I}_{d}} \qquad [ Equation 3 ]$$

In Equation 3, I₁(n) (where n=1, 2, . . . . N) represents the first flare detection pixel values obtained when capturing a uniform luminance surface N times, and I₂(n) (where n=1, 2, . . . . N) represents the second flare detection pixel values obtained when capturing the uniform luminance surface N times, and I_{d} represents the black level. The second threshold may be a minimum value among the values of R(n), and the third threshold may be a maximum value among the values of R(n).

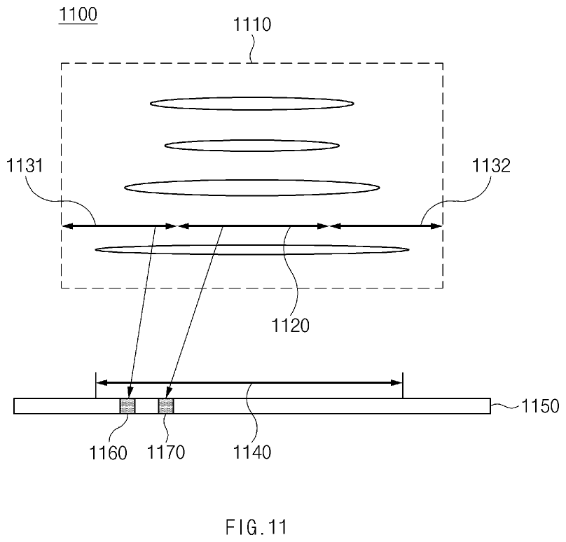

FIG. 11 is a diagram illustrating an image sensing device 1100 according to an embodiment of the present disclosure.

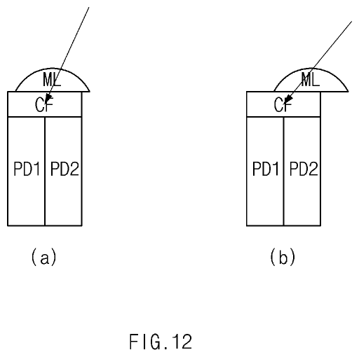

FIG. 12 is a diagram illustrating an offset according to an embodiment of the present disclosure.

FIG. 11 will be described in detail with reference to FIG. 12.

Referring to FIG. 11, an image sensing device 1100 according to an embodiment of the present disclosure may include a main lens 1110 and a pixel region 1150.

The main lens 1110 may include lenses that collect light and direct the collected light to be incident upon the pixels.

Depending on the configuration of the main lens 1110, the range of the exit pupil 1120, the outer sides (1131, 1132) of the exit pupil 1120, and the range of the image circle 1140 may be determined. In general, light is incident from the exit pupil 1120 onto the pixel region 1150. However, when lens flare occurs, there may also be light incident from the outer sides (1131, 1132) of the exit pupil 1120 onto the pixel region 1150.

The pixel region 1150 may include flare detection pixels 1160 and image pixels 1170.

The flare detection pixel 1160 may generate a flare detection signal by detecting flare light. The flare detection pixel 1160 may be disposed inside the image circle 1140. Light may be incident from the outer sides (1131, 1132) of the exit pupil 1120 toward the inside of the image circle 1140. Therefore, since the flare detection pixel 1160 is disposed inside the image circle 1140, the flare detection pixel 1160 may detect flare light. As shown in FIG. 11, the flare light may be incident from the right side with respect to the center of the flare detection pixel 1160. For example, referring to FIG. 12, as illustrated in (a) of FIG. 12, the flare light may be incident from the right side with respect to the center of the photodiodes (PD1, PD2). Accordingly, the microlens (ML) may be disposed over the color filter (CF), which may be a transparent filter, and may be shifted in a direction toward the right side from the center of the color filter (CF).

The image pixel 1170 may generate an image signal. The image signal may be used to generate an image. The image pixel 1170 may be disposed inside the image circle 1140. Light for image generation may be incident upon the image pixel 1170 from the exit pupil 1120, and may be incident from the right side with respect to the center of the image pixel 1170. For example, referring to FIG. 12, as illustrated in (b) of FIG. 12, the light for image generation may be incident from the right side with respect to the center of the photodiodes (PD1, PD2). Accordingly, the microlens (ML) may be disposed over the color filter (CF) and may be shifted in a direction toward the right side from the center of the color filter (CF). The magnitude of the offset of the microlens (ML) shown in (b) of FIG. 12(b) may be greater than the magnitude of the offset of the microlens (ML) shown in (a) of FIG. 12. In addition, since both the microlens (ML) of (a) of FIG. 12 and the microlens (ML) of (b) of FIG. 12 are shifted to the right with respect to the center of the pixel, the sign of the offset of the microlens (ML) of (a) of FIG. 12 may be identical to the sign of the offset of the microlens (ML) of (b) of FIG. 12.

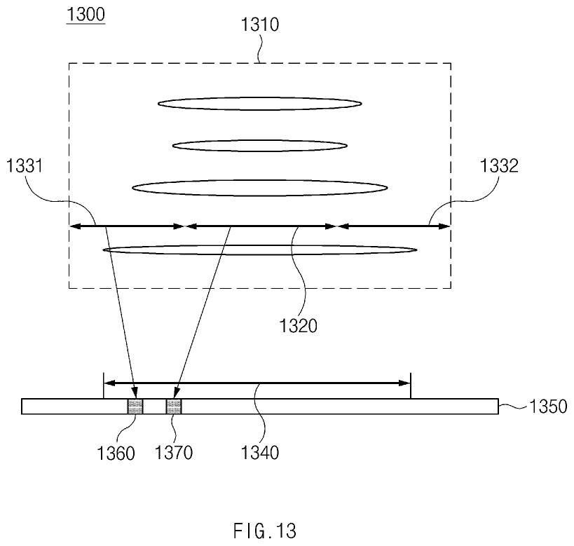

FIG. 13 is a diagram illustrating an image sensing device 1300 according to an embodiment of the present disclosure.

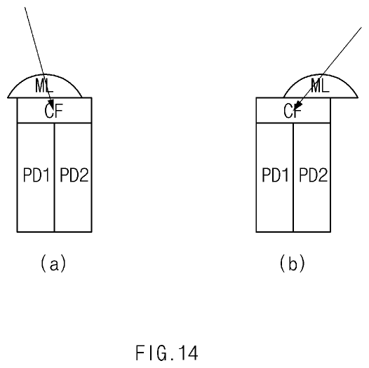

FIG. 14 is a diagram illustrating an offset according to an embodiment of the present disclosure.

FIG. 13 will be described in detail with reference to FIG. 14.

Referring to FIG. 13, the image sensing device 1300 according to an embodiment of the present disclosure may include a main lens 1310 and a pixel region 1350.

The main lens 1310 may include lenses that collect light and direct the collected light to be incident upon the pixels.

Depending on the configuration of the main lens 1310, the range of the exit pupil 1320, the outer sides (1331, 1332) of the exit pupil 1320, and the range of the image circle 1340 may be determined. In general, light is incident from the exit pupil 1320 onto the pixel region 1350. However, when lens flare occurs, there may also be light incident from the outer sides (1331, 1332) of the exit pupil onto the pixel region 1350.

The pixel region 1350 may include flare detection pixels 1360 and image pixels 1370.

The flare detection pixel 1360 may generate a flare detection signal by detecting flare light. The flare detection pixel 1360 may be disposed inside the image circle 1340. Light may be incident from the outer sides (1131, 1132) of the exit pupil 1320 toward the inside of the image circle 1340. Therefore, since the flare detection pixel 1360 is disposed inside the image circle 1340, the flare detection pixel 1360 may detect flare light. As shown in FIG. 13, the flare light may be incident from the left side with respect to the center of the flare detection pixel 1360. For example, referring to FIG. 14, as illustrated in (a) of FIG. 14, the flare light may be incident from the left side with respect to the center of the photodiodes (PD1, PD2). Accordingly, the microlens (ML) may be disposed over the color filter (CF), which may be a transparent filter, and may be shifted in a direction toward the left side from the center of the color filter (CF).

The image pixel 1370 may generate an image signal. The image signal may be used to generate an image. The image pixel 1370 may be disposed inside the image circle 1340. Light for image generation may be incident upon the image pixel 1370 from the exit pupil 1320, and may be incident from the right side with respect to the center of the image pixel 1370. For example, referring to FIG. 14, as illustrated in (b) of FIG. 14, the light for image generation may be incident from the right side with respect to the center of the photodiodes (PD1, PD2). Accordingly, the microlens (ML) may be disposed over the color filter (CF) and may be shifted in a direction toward the right side from the center of the color filter (CF). The magnitude of the offset of the microlens (ML) shown in (b) of FIG. 14 may be greater than the magnitude of the offset of the microlens (ML) shown in (a) of FIG. 14. In addition, since both the microlens (ML) of (a) of FIG. 14 and the microlens (ML) of (b) of FIG. 14 are shifted to different directions, e.g., left and right directions, with respect to the center of the pixel, the sign of the offset of the microlens (ML) of (a) of FIG. 14 may be different from the sign of the offset of the microlens (ML) of (b) of FIG. 14.

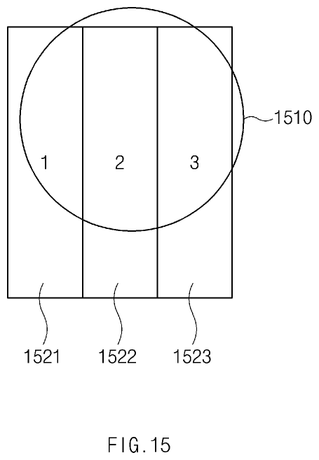

FIG. 15 is a diagram illustrating an imaging system according to an embodiment of the present disclosure.

Referring to FIG. 15, the imaging system according to an embodiment of the present disclosure may include a first flare detection pixel 1521, a second flare detection pixel 1522, and a third flare detection pixel 1523, all of which share a single microlens 1510.

The first flare detection pixel 1521 may generate a first flare detection signal, the second flare detection pixel 1522 may generate a second flare detection signal, and the third flare detection pixel 1523 may generate a third flare detection signal.

A readout circuit included in the image sensing device of the imaging system may generate a first flare detection pixel value based on the first flare detection signal, a second flare detection pixel value based on the second flare detection signal, and a third flare detection pixel value based on the third flare detection signal.

The image processing device may determine whether flare has occurred based on the first flare detection pixel value, the second flare detection pixel value, and the third flare detection pixel value. For example, when a first ratio of a first value, which is obtained by subtracting a black level from the first flare detection pixel value, to a second value, which is obtained by subtracting a black level from the second flare detection pixel value, is less than a first lower limit value, the image processing device may determine that flare has occurred. In addition, when the first ratio is greater than a first upper limit value, the image processing device may determine that flare has occurred.

In addition, when a second ratio of a first value, which is obtained by subtracting a black level from the first flare detection pixel value, to a third value, which is obtained by subtracting a black level from the third flare detection pixel value, is less than a second lower limit value, the image processing device may determine that flare has occurred. In addition, when the second ratio is greater than a second upper limit value, the image processing device may determine that flare has occurred. The above-described results can be expressed mathematically as shown in Equations 4, 5, 6, 7, 8 and 9.

$${R}_{12} = \frac{{I}_{1} - {I}_{d}}{{I}_{2} - {I}_{d}} \qquad [ Equation 4 ]$$

$${R}_{13} = \frac{{I}_{1} - {I}_{d}}{{I}_{3} - {I}_{d}} \qquad [ Equation 5 ]$$

$${R}_{12} < {R}_{lower , 12} \qquad [ Equation 6 ]$$

$${R}_{12} > {R}_{upper , 12} \qquad [ Equation 7 ]$$

$${R}_{13} < {R}_{lower , 13} \qquad [ Equation 8 ]$$

$${R}_{13} > {R}_{upper , 13} \qquad [ Equation 9 ]$$

In Equations 4 to 9, I₁ represents the first flare detection pixel value, I₂ represents the second flare detection pixel value, I₃ represents the third flare detection pixel value, R₁₂ represents the first ratio, R₁₃ represents the second ratio, R_{lower,12} represents the first lower limit value, R_{upper,12} represents the first upper limit value, R_{lower,13} represents the second lower limit value, and R_{upper,13} represents the second upper limit value.

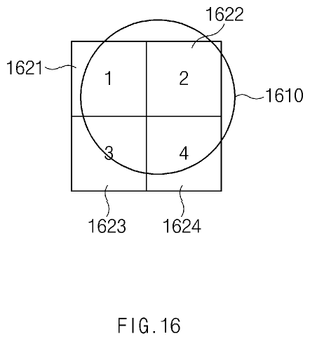

FIG. 16 is a diagram illustrating an imaging system according to an embodiment of the present disclosure.

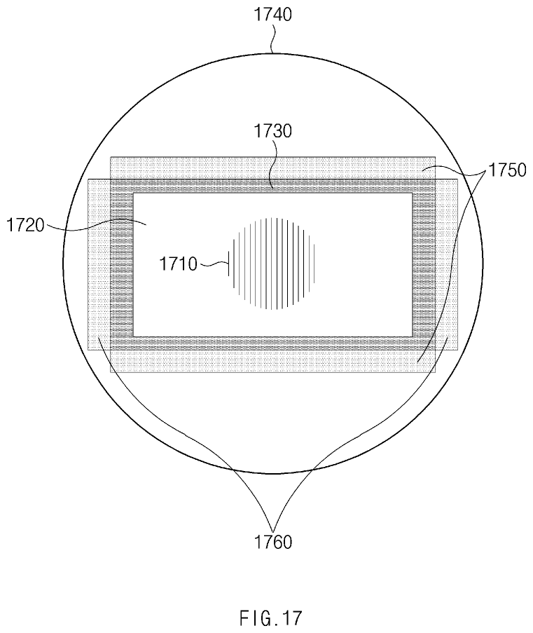

FIG. 17 is a diagram illustrating an imaging system according to an embodiment of the present disclosure.

FIG. 16 will be described in detail with reference to FIG. 17.

Referring to FIG. 16, an imaging system according to an embodiment of the present disclosure may include a first flare detection pixel 1621, a second flare detection pixel 1622, a third flare detection pixel 1623, and a fourth flare detection pixel 1624, all of which share a microlens 1610.

The first flare detection pixel 1621 may generate a first flare detection signal, the second flare detection pixel 1622 may generate a second flare detection signal, the third flare detection pixel 1623 may generate a third flare detection signal, and the fourth flare detection pixel 1624 may generate a fourth flare detection signal.

A readout circuit included in the image sensing device of the imaging system may generate a first flare detection pixel value based on the first flare detection signal, a second flare detection pixel value based on the second flare detection signal, a third flare detection pixel value based on the third flare detection signal, and a fourth flare detection pixel value based on the fourth flare detection signal.

The image processing device may determine whether flare has occurred based on the first flare detection pixel value, the second flare detection pixel value, the third flare detection pixel value, and the fourth flare detection pixel value. For example, when a third ratio of a first value, which is obtained by subtracting twice the black level from the sum of the first flare detection pixel value and the third flare detection pixel value, to a second value, which is obtained by subtracting twice the black level from the sum of the second flare detection pixel value and the fourth flare detection pixel value, is less than a third lower limit value, the image processing device may determine that flare has occurred. In addition, when the third ratio is greater than a third upper limit value, the image processing device may determine that flare has occurred.

In addition, when a fourth ratio of a third value, which is obtained by subtracting twice the black level from the sum of the first flare detection pixel value and the second flare detection pixel value, to a fourth value, which is obtained by subtracting twice the black level from the sum of the third flare detection pixel value and the fourth flare detection pixel value, is less than a fourth lower limit value, the image processing device may determine that flare has occurred. Furthermore, when the fourth ratio is greater than a fourth upper limit value, the image processing device may determine that flare has occurred. The above-described results can be expressed mathematically as represented by Equations 10, 11, 12, 13, 14 and 15.

$${R}_{LR} = \frac{{I}_{1} + {I}_{3} - 2 {I}_{D}}{{I}_{2} + {I}_{4} - 2 {I}_{D}} \qquad [ Equation 10 ]$$

$${R}_{TB} = \frac{{I}_{1} + {I}_{2} - 2 {I}_{D}}{{I}_{3} + {I}_{4} - 2 {I}_{D}} \qquad [ Equation 11 ]$$

$${R}_{L R} > {R}_{LR , upper} \qquad [ Equation 12 ]$$

$${R}_{L R} < {R}_{LR , lower} \qquad [ Equation 13 ]$$

$${R}_{T B} > {R}_{TB , upper} \qquad [ Equation 14 ]$$

$${R}_{T B} < {R}_{TB , lower} \qquad [ Equation 15 ]$$

In Equations 10 to 15, I₁ represents the first flare detection pixel value, I₂ represents the second flare detection pixel value, I₃ represents the third flare detection pixel value, I₄ represents the fourth flare detection pixel value, R_{LR} represents the third ratio, R_{TB} represents the fourth ratio, R_{LR,lower} represents the third lower limit value, R_{LR,upper} represents the third upper limit value, R_{TB,lower} represents the fourth lower limit value, and R_{TB,upper} represents the fourth upper limit value.

Referring to FIG. 17, the image sensing device may include an image pixel region 1720, an optical black region 1730, a first flare detection pixel region 1750, and a second flare detection pixel region 1760. FIG. 17 shows an exit pupil 1710 and an image circle 1740.

The first flare detection pixel 1621, the second flare detection pixel 1622, the third flare detection pixel 1623, and the fourth flare detection pixel 1624 may be included in at least one of the first flare detection pixel region 1750 or the second flare detection pixel region 1760. For example, when the first flare detection pixel 1621, the second flare detection pixel 1622, the third flare detection pixel 1623, and the fourth flare detection pixel 1624 are included in the first flare detection pixel region 1750, the image processing device may determine whether flare has occurred by using the above-described Equation 10, Equation 12, and Equation 13. In other words, when the result calculated through Equation 10 satisfies the condition of Equation 12 or Equation 13, the image processing device may determine that flare has occurred.

Alternatively, when the first flare detection pixel 1621, the second flare detection pixel 1622, the third flare detection pixel 1623, and the fourth flare detection pixel 1624 are included in the second flare detection pixel region 1760, the image processing device may determine whether flare has occurred by using the above-described Equation 11, Equation 14, and Equation 15. In other words, when the result calculated through Equation 11 satisfies the condition of Equation 14 or Equation 15, the image processing device may determine occurrence of the flare.

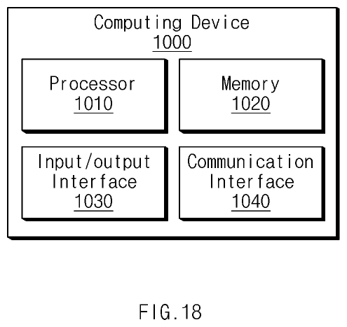

FIG. 18 is a block diagram showing an example of a computing device corresponding to the image processing device of FIG. 1.

Referring to FIG. 18, computing device 1000 may illustrate a hardware configuration for performing the operation of the image processing device 200 of FIG. 1.

In some embodiments, the computing device 1000 may be mounted on a chip that is separate from the chip on which the image sensing device is mounted. In some embodiments, the chip on which the image sensing device is mounted and the chip on which the computing device 1000 is mounted may be integrated in a single package, for example, a multi-chip package (MCP), but they are not limited thereto.

Additionally, the internal configuration or arrangement of the computing device 1000 and the image sensing device may vary depending on the embodiments. For example, at least a portion of the image sensing device may be included in the computing device 1000. Alternatively, at least a portion of the computing device 1000 may be included in the image sensing device. In the latter case, at least a portion of the computing device 1000 may be mounted together on a chip on which the image sensing device is mounted.

The computing device 1000 may include a processor 1010, a memory 1020, an input/output (I/O) interface 1030, and a communication interface 1040.

The processor 1010 may process data and/or instructions required to perform the operations of the components of the image processing device 200 described in FIG. 1.

The memory 1020 may store data and/or instructions required to perform operations of the components of the image processing device 200, and may be accessed by the processor 1010. For example, the memory 1020 may be volatile memory (e.g., Dynamic Random Access Memory (DRAM), Static Random Access Memory (SRAM), etc.) or non-volatile memory (e.g., Programmable Read Only Memory (PROM), Erasable PROM (EPROM), Electrically Erasable PROM (EEPROM), flash memory, etc.).

That is, the computer program for performing the operations of the image processing device 200 disclosed in the present disclosure may be stored in the memory 1020 and executed by the processor 1010, thereby implementing the operations of the image processing device 200.

The input/output (I/O) interface 1030 may connect an external input device, e.g., keyboard, mouse, touch panel, etc., and/or an external output device, e.g., display, to the processor 1010, to allow data to be transmitted and received.

The communication interface 1040 may transmit and receive various data to and from an external device, e.g., an application processor, external memory, etc., and may be a device configured to support wired or wireless communication.

As described above, the imaging system according to various embodiments of the present disclosure may determine whether flare has occurred by using pixel values of flare detection pixels.

Since the image sensing device according to the embodiments of the present disclosure may include high-sensitivity pixels arranged in the direction in which flare light is incident, the image sensing device may accurately determine occurrence or non-occurrence of flare by using the high-sensitivity pixels.

The embodiments of the present disclosure may provide various effects that can be directly or indirectly recognized through the present disclosure.

Those skilled in the art will appreciate that the present disclosure may be carried out in other specific ways than those set forth herein. In addition, claims that are not explicitly presented in the appended claims may be combined as an embodiment or a new claim through subsequent amendment after filing.

Although a number of embodiments have been described, it should be understood that modifications and enhancements can be made to the disclosed embodiments, and other embodiments can be implemented based on the descriptions and illustrations of the present disclosure.

What is claimed is:

1. An image sensing device comprising:
a first flare detection photodiode configured to generate a flare detection signal;
a first filter disposed over the first flare detection photodiode; and
a first microlens disposed over the first filter to be shifted from a central axis of the first filter by a first offset corresponding to a first angle of incidence of flare light upon the first flare detection photodiode.

2. The image sensing device according to claim 1, wherein the first angle of incidence of the flare light corresponds to an angle of incidence of light incident upon the first flare detection photodiode from outside an exit pupil.

3. The image sensing device according to claim 1, further comprising:
an image photodiode configured to generate an image signal;
a second filter disposed over the image photodiode; and
a second microlens disposed over the second filter to be shifted from a central axis of the second filter by a second offset,
wherein a magnitude of the first offset is smaller than a magnitude of the second offset.

4. The image sensing device according to claim 3, wherein the second offset corresponds to a second angle of incidence of light incident upon the image photodiode from an exit pupil.

5. The image sensing device according to claim 3, wherein the first offset has a sign identical to the second offset.

6. The image sensing device according to claim 3, wherein the first offset has a sign different from the second offset.

7. The image sensing device according to claim 3, wherein the second filter is a color filter including at least one color selected from red, green, or blue.

8. The image sensing device according to claim 1, wherein the first filter is a transparent filter.

9. The image sensing device according to claim 1, wherein the first flare detection photodiode is disposed inside an image circle.

10. The image sensing device according to claim 9, wherein the first flare detection photodiode is disposed inside an optical black region.

11. The image sensing device according to claim 9, wherein the first flare detection photodiode is disposed outside an optical black region.

12. The image sensing device according to claim 1, wherein the first flare detection photodiode is disposed outside an image circle.

13. The image sensing device according to claim 1, further comprising a second flare detection photodiode disposed adjacent to the first flare detection photodiode,
wherein the first filter is disposed over both the first flare detection photodiode and the second flare detection photodiode.

14. An imaging system comprising:
an image sensing device including
a first flare detection pixel configured to detect flare light incident from outside an exit pupil to generate a first flare detection signal, and
a readout circuit configured to generate a first flare detection pixel value based on the first flare detection signal; and
an image processing device configured to determine whether flare has occurred based on the first flare detection pixel value.

15. The imaging system according to claim 14, wherein the first flare detection pixel is disposed outside an image circle.

16. The imaging system according to claim 15, wherein the image processing device is configured to determine that the flare has occurred when the first flare detection pixel value is equal to or greater than a first threshold.

17. The imaging system according to claim 14, wherein:
the image sensing device includes a second flare detection pixel that shares a microlens with the first flare detection pixel and is configured to detect the flare light incident from outside the exit pupil to generate a second flare detection signal;
the readout circuit is configured to generate a second flare detection pixel value based on the second flare detection signal; and
the image processing device is configured to determine whether the flare has occurred based on the first flare detection pixel value and the second flare detection pixel value.

18. The imaging system according to claim 17, wherein the first flare detection pixel and the second flare detection pixel are disposed inside an image circle and outside an optical black region.

19. The imaging system according to claim 17, wherein:
the image processing device is configured to determine that the flare has occurred when a ratio of a first value to a second value is less than a second threshold or greater than a third threshold, and
the first value is obtained by subtracting a black level from the first flare detection pixel value, and the second value is obtained by subtracting the black level from the second flare detection pixel value.

20. An imaging system comprising:
an image sensing device including
a first flare detection photodiode configured to generate a first flare detection signal,
a second flare detection photodiode configured to generate a second flare detection signal,
a transparent filter disposed over both the first flare detection photodiode and the second flare detection photodiode,
a microlens disposed over the transparent filter with an offset corresponding to an angle of incidence of light incident upon the first flare detection photodiode or the second flare detection photodiode from outside an exit pupil, and
a readout circuit configured to generate a first flare detection pixel value based on the first flare detection signal and to generate a second flare detection pixel value based on the second flare detection signal; and
an image processing device configured to determine whether flare has occurred based on the first flare detection pixel value, the second flare detection pixel value, and a black level.
